(19) United States
(12) Patent Application Publication
(10) Pub. No.: US 2023/0274044 A1
(43) Pub. Date: Aug. 31, 2023

(54) CRITICAL INFRASTRUCTURE PROTECTION BLUEPRINTS GENERATION AND UTILIZATION IN AN INTERDEPENDENT CRITICAL INFRASTRUCTURE ARCHITECTURE

(71) Applicant: Inlecom Group BV, Bruxelles (BE)

(72) Inventors: Panayotis Katsoulakos, Haywards Heath (GB); Patrick J. O'Sullivan, Dublin (IE); Jenny Rainbird, Bexleyheath (GB); Mark Richard Bennett, Leicestershire (GB)

(73) Assignee: Inlecom Group BV, Bruxelles (BE)

(21) Appl. No.: 17/682,620

(22) Filed: Feb. 28, 2022

(51) Int. Cl. G06F 30/13

(52) U.S. Cl. CPC G06F 30/13

(57) ABSTRACT

Critical infrastructure (CI) protection blueprint generation in an interdependent CI architecture includes constructing a digital twin of a heterogeneous collection of CI elements associated with respectively different services provided to a common community. Thereafter, hypothetical sensor data is specified in the digital twin for a target CI element in the hierarchy. In response, sensor data is read for other CI elements dependent upon the target CI element so as to identify impacted CI elements. For each impacted CI element, additional sensor data is read for further CI elements in the hierarchy dependent upon the impacted CI elements and the process repeats until no additional impacted CI elements are identified. A listing of all impacted CI elements is written to a blueprint for the hierarchy in association with the hypothetical sensor data in order to define a cascading effect of the hypothetical sensor data upon the hierarchy within the digital twin.

### BACKGROUND OF THE INVENTION

### Field of the Invention

The present invention relates to the technical field of infrastructure modeling and more particularly to the modeling of an impact of an adverse event upon a hierarchy of interdependent critical infrastructure nodes.

### Description of the Related Art

Critical infrastructure (CI) refers to those community structural devices delivering critical services to a community. Examples include elements of the public water supply and distribution network, elements of the cellular telephonic communications network, elements of the electric power distribution network, elements of the natural gas distribution network, roadways, waterways, airports, railways, bridges and tunnels and so forth. In the modern era, much of the operability and tunability of CI elements in a community depend upon the proper and secure functioning of computing devices sensing the state of affairs in the respective CI elements and commanding the operation of electromechanical control elements in response to the sensed state of affairs. Thus, the failure of a computational controller for a given CI element often will result in the failure of the given CI element itself.

In the case of an ordinary control system controlling a single structural element, such as a machine in a factory, one must monitor the operation of the control system and the operation of the machine only, since the failure only impacts the operation of the machine. However, in many instances, different controlled machines depend upon other controlled machines such that the failure of one machine can cascade in impact upon other machines within a hierarchy of machines. Yet, in the circumstance of an interdependent hierarchy of machines in a factory, an overlord process can monitor the entirety of the hierarchy and the corresponding controllers in order to appreciate the impact of an exception in one of the machines upon interdependent others of the machines.

In the case of interdependent CI elements in a community, so much is not the case. To wit, in a typical geographically definable community, different CI elements not only may be geographically disbursed about a large area—much larger than any ordinary factory, but the geographically disbursed CI elements may be managed by different individuals or teams of individuals and in some cases, by different teams of individuals not adapted to share in real time the health of any given CI element and its corresponding controller. Further, as is most often the case, different CI elements in the community often relate to completely different organizations providing completely different services to the community, such as wastewater management, telecommunications and power distribution.

The problem of heterogeneous CI elements supporting the delivery of heterogeneous services to a community affects the manner in which community managers prepare for adverse events. In the instance of a single service provider in the community for a single community service, one can model the operation of corresponding CI elements in support of the delivery of the single community service and the behavior of those CI elements in the face of an adverse event. However, in so far as different service providers in a community lack data sharing and connectivity, no modeling heretofore has been possible as to the impact of a fault condition in one CI element of one service provider providing one service to the community, upon one or more CI elements of other service providers for the community providing other services to the community.

### BRIEF SUMMARY OF THE INVENTION

Embodiments of the present invention address technical deficiencies of the art in respect to modeling the effects of an adverse fault condition upon a CI element of a service provider to a community with respect to other CI elements of other service providers to the community. To that end, embodiments of the present invention provide for a novel and non-obvious method for CI protection blueprint generation and utilization in an interdependent CI architecture. Embodiments of the present invention also provide for a novel and non-obvious computing device adapted to perform the foregoing method. Finally, embodiments of the present invention provide for a novel and non-obvious data processing and reasoning system incorporating the foregoing device in order to perform the foregoing method.

In one embodiment of the invention, a method for CI protection blueprint generation and utilization in an interdependent CI architecture includes the construction, in memory of a computer, of a digital twin of a heterogeneous collection of CI elements associated with respectively different services provided to a common community. In order to construct the digital twin, first a hierarchy of the CI elements in the collection can be defined and then different ones of the CI elements in the hierarchy can be associated with other CI elements in the hierarchy so as to create a dependency relationship therebetween. Then, sensor data can be received from each of the CI elements in the hierarchy over a defined period of time and can include, for example, sensed valve states, switch states, measured temperatures, pressures, water levels, light levels, humidity, weather conditions, date and time information and remotely acquired video imagery from terrestrial and extraterrestrial image sensors. Finally, observed performance data can be correlated to the sensor data, such that the correlation, for each one of the CI elements in the hierarchy, models different states of operation resulting from different conditions reflected by the sensor data including sensed states of operation of dependent ones of the CI elements in the hierarchy.

Once the digital twin has been constructed, hypothetical sensor data can be specified in the digital twin for a target one of the CI elements in the hierarchy. Then, in response to the specification of the hypothetical sensor data, sensor data can be read for the other CI elements that are dependent upon the target one of the CI elements in the hierarchy. A new state is then computed in the digital twin for each one of the other CI elements so that the new state for each one of the other CI elements can be compared to a previously computed state in order to identify impacted ones of the CI elements. For each impacted one of the CI elements, additional sensor data can be read for further CI elements in the hierarchy that are dependent upon the impacted CI elements, a new state computed in the digital twin of each further one of the CI elements in the hierarchy and the new state for each further one of the CI elements compared to a previously computed state in order to identify further impacted CI elements. Finally, the process can repeat until no additional impacted CI elements are identified. As such, a listing of all impacted ones of the CI elements can be written to a blueprint for the hierarchy in association with the hypothetical sensor data in order to define a cascading effect of the hypothetical sensor data upon the hierarchy within the digital twin.

In one aspect of the embodiment, the hypothetical sensor data is received from over a communications network by an authenticated end user of the digital twin. In another aspect of the embodiment, the hypothetical sensor data is a collection of sensed data for correspondingly different ones of the CI elements. In yet another aspect of the embodiment, the method additionally includes inserting into the blueprint, at least one configuration parameter for a corresponding one of the impacted CI elements associated with a remediation of the cascading event. In even yet another aspect of the embodiment, the method additionally can include receiving from over a computer communications network, a specification of a different hierarchy of CI elements, comparing the different hierarchy with the defined hierarchy and, on the condition that different hierarchy threshold matches the defined hierarchy, transmitting the blueprint over the computer communications network in response to the receipt of the specification.

In another embodiment of the invention, a data processing system is adapted for CI protection blueprint generation and utilization in an interdependent CI architecture. The system includes a multiplicity of different device sensors affixed to different CI elements associated with respectively different services provided to a common community. The system also includes a host computing platform with one or more computers, each with memory and one or processing units including one or more processing cores, and a network interface communicatively coupled over a computer communications network to each of the different device sensors. Finally, the system includes a blueprint generation module. The blueprint generation module includes computer program instructions enabled while executing in the memory of at least one of the processing units of the host computing platform to construct in the memory a digital twin of a heterogeneous collection of the CI elements.

Specifically, the program instructions define a hierarchy of the CI elements in the collection, associate different ones of the CI elements in the hierarchy with other ones of the CI elements in the hierarchy so as to create a dependency relationship therebetween, receive sensor data from each of the CI elements in the hierarchy over a defined period of time and correlate observed performance data to the sensor data, the correlation, for each one of the CI elements in the hierarchy, modeling different states of operation resulting from different conditions reflected by the sensor data including sensed states of operation of dependent ones of the CI elements in the hierarchy.

The program instructions then specify in the digital twin, hypothetical sensor data for a target one of the CI elements in the hierarchy. In response to the specification of the hypothetical sensor data, the program instructions read sensor data of the other ones of the CI elements dependent upon the target one of the CI elements in the hierarchy and compute a new state in the digital twin of each one of the other ones of the CI elements and compare the new state for each one of the other ones of the CI elements to a previously computed state in order to identify impacted ones of the CI elements. Then, for each impacted CI element, additional sensor data of further ones of the CI elements in the hierarchy that are dependent upon the impacted ones of the CI elements can be read, and a new state computed in the digital twin of each further one of the CI elements in the hierarchy and the new state for each further one of the CI elements compared to a previously computed state in order to identify further impacted ones of the CI elements. Finally, the program instructions repeat the additional reading, computing and comparing until no additional impacted CI elements are identified. Then a listing of all impacted ones of the CI elements can be added to a blueprint for the hierarchy in association with the hypothetical sensor data in order to define a cascading effect of the hypothetical sensor data upon the hierarchy within the digital twin.

In this way, the technical deficiencies of conventional planning for fault conditions in a CI element in a community are overcome owing to the ability to model within a digital twin the cascading effect of a fault condition in CI element in a hierarchy of dependent CI elements even though the CI elements may be managed and thus monitored by disparate parties. Further, by developing a blueprint for one collection of modeled, interdependent CI elements, the blueprint then can be applied to another collection of similar, modeled, interdependent CI elements without necessitating the development of a blueprint separatley for the new collection of similar, modeled, interdependent CI elements. Additional aspects of the invention will be set forth in part in the description which follows, and in part will be obvious from the description, or may be learned by practice of the invention. The aspects of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The accompanying drawings, which are incorporated in and constitute part of this specification, illustrate embodiments of the invention and together with the description, serve to explain the principles of the invention. The embodiments illustrated herein are presently preferred, it being understood, however, that the invention is not limited to the precise arrangements and instrumentalities shown, wherein:

FIG. 1 is a pictorial illustration reflecting different aspects of a process of CI protection blueprint generation and utilization in an interdependent CI architecture;

FIG. 2 is a block diagram depicting a data processing system adapted to perform one of the aspects of the process of FIG. 1; and,

FIG. 3 is a flow chart illustrating one of the aspects of the process of FIG. 1.

### DETAILED DESCRIPTION

Embodiments of the invention provide for CI protection blueprint generation and utilization in an interdependent CI architecture. In accordance with an embodiment of the invention, a hierarchy of different CI elements for a community may be modeled within a digital twin. The CI elements may include critical infrastructure facilities such as water treatment and water management, water supply, power generation and distribution, traffic control, telecommunications, and the like. Each CI element is adapted for digital communication of state through the use of IoT deviceware. The digital twin models the hierarchy by including in the digital twin, for each CI element, a corresponding node with state, with the joining of the nodes reflective of CI elements being dependent upon one another unidirectionally or bidirectionally, by relationship defining edges.

Each of the nodes in the digital twin include one or more settings defining ranges of operation, rules for responding to certain states, and the activation or deactivation of functional portions of the corresponding CI element. Once the digital twin has been generated for the hierarchy of dependent CI elements, a hypothetical state can be imposed upon a target node amongst the nodes. Resulting state information can be determined for each directly dependent node in the digital twin determined from an application of the settings upon the state of the target node so as to determine which nodes suffer a change in state resulting from the change in state of the target node.

Then, the process can repeat for those of the nodes dependent upon the nodes in which a state change has resulted from the state change in the target node so as to record a cascading effect of the state change in the target node. And again, the process can continue to repeat until no observed nodes show a state change resulting from a change in state of a node upon which the observed node is dependent. A listing of all impacted nodes are then written to a blueprint for the hierarchy modeled in the digital twin in association with the hypothetical state change. The blueprint then defines a cascading effect of the hypothetical state change upon the hierarchy within the digital twin so that changes in the settings of the different nodes can be tested to minimize the cascading effect of the hypothetical state change in the target node of the digital twin. The settings of the digital twin can then be transformed to actual settings in the actual CI elements of the dependency hierarchy modeled by the digital twin.

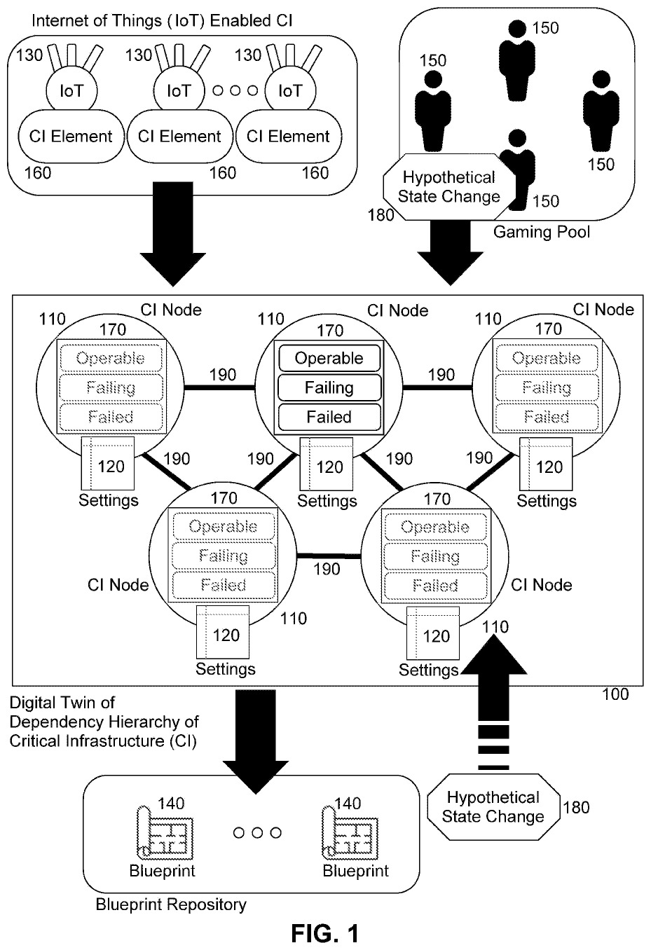

In illustration of one aspect of the embodiment, FIG. 1 pictorially shows a process of CI protection blueprint generation and utilization in an interdependent CI architecture. As shown in FIG. 1, an arrangement of CI elements 160 in a dependency hierarchy can be instrumented with respectively different Internet of Things (IoT) devices 130 reporting a contemporaneous state for a respective one of the CI elements 160 and for applying settings to the state in order to determine if the contemporaneous state changes. The CI elements 160 and state thereof reported by the IoT devices 130 are then modeled within a digital twin 100 in which different CI nodes 110 correspond to different CI elements 160 of the respective IoT devices 130. Each of the CI nodes 110 includes a set of states 170, such as operable, failing and failed, or represented by color such as red, amber, green. Each of the CI nodes 110 further include one or more settings 120 defining in part, how each of the CI nodes 110 changes its state 170 in response to a state change in another of the CI nodes 110 connected thereto by a dependency relationship 190.

With the digital twin 100 defined for the CI elements 160 in the dependency hierarchy, a hypothetical state 180 can be specified for one of the CI nodes 110. In this regard, the hypothetical state 180 can be specified manually, or the hypothetical state 180 can be received remotely from one or more authenticated users 150 in a gaming pool from which the response of the digital twin 100 can be observed in respect to the hypothetical state change 180 in a target one of the CI Nodes 110 of the digital twin 100. Specifically, in response to the imposition of a hypothetical state change 180 in a target one of the CI nodes 110, the settings 120 of other CI nodes 110 with a dependency relationship 190 to the target one of the CI nodes 110 can be applied to the hypothetical state change 180 so as to determine whether or not a resulting hypothetical state of the dependent one of the CI nodes 110 has changed.

For each one of the dependent one of the CI nodes 110 determined to have a corresponding state change, the process can repeat with respect to others of the CI nodes 110 in a direct dependency relationship 190. This process continues until it is determined that no additional ones of the CI nodes 110 in a dependency relationship 190 with an observed one of the CI nodes 110 experiencing a state change, themselves experience a state change. Thus, a listing of the ones of the CI nodes 110 having experienced a state change as a cascading consequence of the hypothetical state change 180 imposed upon the target one of the CI nodes 110 can be recorded in a blueprint 140 along with the settings 120 of each of the CI nodes 110. Different ones of the settings 120 can be modified in the blueprint 140 in order to determine if a reduction in the cascading consequence of the hypothetical state change 180 imposed upon the target one of the CI nodes 110 can be achieved. Thereafter, the settings 120 of the blueprint 140 can be applied to the CI elements 160.

Notably, once a blueprint 140 has been defined for a specific dependency hierarchy of the CI elements 160, a subsequent hierarchy of the CI elements 160 can be defined with different interdependencies. The subsequent hierarchy can be modeled and compared to the digital twin 100. To the extent that the subsequent hierarchy matches the digital twin within a threshold of similarity in structure, the blueprint 140 for the digital twin 100 can be applied to the subsequent hierarchy as a pre-determined optimization of minimization of a cascading effect of a state change in a CI element of the subsequent hierarchy.

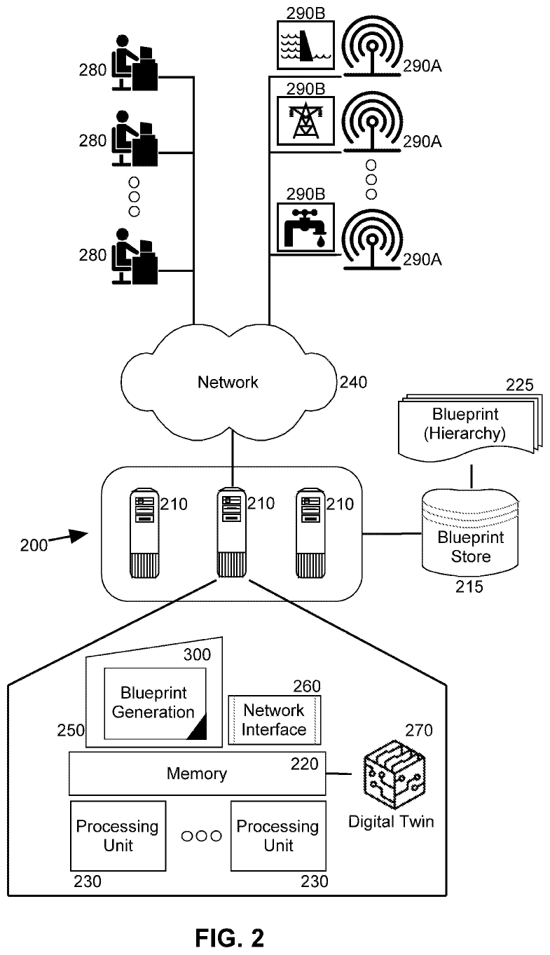

Aspects of the process described in connection with FIG. 1 can be implemented within a data processing system. In further illustration, FIG. 2 schematically shows a data processing system adapted to perform CI protection blueprint generation and utilization in an interdependent CI architecture. In the data processing system illustrated in FIG. 1, a host computing platform 200 is provided. The host computing platform 200 includes one or more computers 210, each with memory 220 and one or more processing units 230. The computers 210 of the host computing platform (only a single computer shown for the purpose of illustrative simplicity) can be co-located within one another and in communication with one another over a local area network, or over a data communications bus, or the computers can be remotely disposed from one another and in communication with one another through network interface 260 over a data communications network 240.

In this regard, different remotely authenticatable end users 280 communicate with the host computing platform 200 from over data communications network 240 by way of the network interface 260. Further, different CI elements 290B communicate through corresponding IoT devices 290A with the host computing platform 200 over the data communications network 240 by way of the network interface 260. The memory 220 includes therein a digital twin 270 modeling a hierarchy of the CI elements 290B. As well, the host computing platform has coupled thereto, fixed storage 215 in which different blueprints 225 are stored, each corresponding to a particular hierarchical structure of the CI elements 290B and each defining a collection of settings for each of the CI elements 290B requisite to minimize the cascading effect of a state change in one of the CI elements 290B.

Notably, a computing device 250 including a non-transitory computer readable storage medium can be included with the data processing system 200 and accessed by the processing units 230 of one or more of the computers 210. The computing device stores 250 thereon or retains therein a program module 300 that includes computer program instructions which when executed by one or more of the processing units 230, performs a programmatically executable process for CI protection blueprint generation and utilization in an interdependent CI architecture. Specifically, the program instructions during execution construct the digital twin 270 by defining a hierarchy of nodes corresponding to the CI elements 290B, associating different ones of the nodes in the hierarchy with other nodes in the hierarchy so as to create a dependency relationship therebetween. One or more parameterized settings are then defined for each of the nodes.

The program instructions then receive sensor data from the IoT devices 290A, either synchronously in real time or asynchronously, with each corresponding to a different one of the CI elements 290B in the hierarchy over a defined period of time. Thereafter, the program instructions correlate observed performance data in the CI elements 290B to the sensor data of the IoT devices 290A. The correlation, for each one of the CI elements 290B in the hierarchy, models different states of operation resulting from different conditions reflected by the sensor data and the settings applied to individual ones of the CI elements 290B including sensed states of operation of dependent ones of the CI elements 290B in the hierarchy. The program instructions then store each correlation in a corresponding one of the nodes for use when exercising the digital twin 270.

In this regard, once the digital twin 270 has been constructed, the program instructions facilitate crowdsourced simulation of the hierarchy by receiving from different ones of the authenticated users 280, a specified hypothetical state change in a target one of the nodes of the digital twin 270. The program instructions then identify all directly dependent nodes in the digital twin 270 for the target one of the nodes and apply the correlations of the dependent nodes to the hypothetical state change in the target one of the nodes to produce an output state for each of the dependent nodes. For every dependent node that produces a state change as an output state, further dependent nodes also are tested to identify state changes. The program instructions repeat this process for every node experiencing a state change cascading from the hypothetical state change in the target one of the nodes until no state changes are detected in any further node.

At this juncture, the program instructions construct a list of the affected nodes in the digital twin 270 as exemplary of the cascading effect of the hypothetical state change. Then, the program code writes the cascading effect of the hypothetical state change to a corresponding one of the blueprints 225 for the hierarchy along with the correlations and settings. One or more of the settings subsequently can be modified for one or more of the nodes and the process performed again to determine if the cascading effect of the hypothetical state change can be reduced. If so, the program instructions write the change in settings to the corresponding one of the blueprints 225.

Notably, at any time, a hierarchy of the CI elements 290B can be specified in the memory 220 of the host computing platform in terms of a collection of nodes arranged according to a dependency graph, and the specification of the hierarchy compared to those of the blueprints 225. On the condition that the specified hierarchy threshold matches the structure of a hierarchy for one of the blueprints 225, such as a threshold number of nodes in the graph in a particular dependency arrangement match those of a hierarchy of one of the blue prints 225, the program instructions then return the digital twin 270 for the one of the blueprints 225 of the threshold matching hierarchy as being sufficient to account for the optimization of the specified hierarchy of the CI elements 290B.

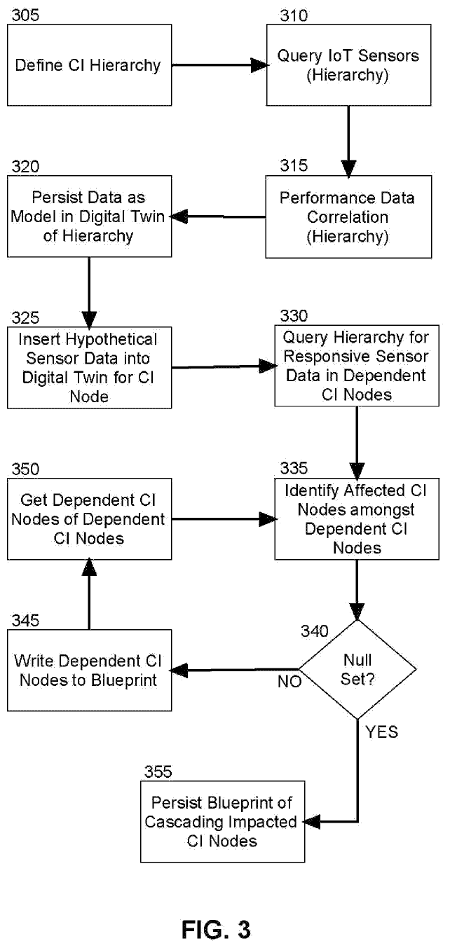

In further illustration of an exemplary operation of the module, FIG. 3 is a flow chart illustrating one of the aspects of the process of FIG. 1. Beginning in block 305, a dependency hierarchy is defined for a collection of CI elements in a community and in block 310, the IoT sensors for each CI element queried for state and performance. In block 315, performance data for each of CI element and corresponding state are correlated and persisted in block 320 as different nodes in a digital twin modeling the dependency hierarchy of the collection of CI elements. In block 325, hypothetical sensor data is specified for one or more of the nodes of the digital twin, corresponding to a target one or more of the CI elements and in block 330, dependent nodes for the target in the digital twin can be interrogated to determine if any have experienced a change in state owing to the hypothetical sensor data specified for the target node or nodes. In block 335, nodes determined to have experienced state changes are identified as cascadingly affected nodes of the digital twin.

In decision block 340, it is determined if the set of nodes determined to have experienced state changes is the null set. If not, in block 345 a listing of the set of nodes determined to have experienced state changes is written to a blueprint for the dependency hierarchy of the collection of CI elements. Then, in block 350, the process repeats with a selection of one or more nodes dependent upon each of the nodes determined to have experienced state changes. Once again, in block 335, a set of nodes amongst the selected which are determined to have experienced state changes are identified as cascadingly affected nodes of the digital twin, and if the set of nodes is determined not to be the null set in decision block 340, a listing of those nodes are also added to the blueprint. In decision block 340, when the set is determined to be the null set, indicating that no further nodes are impacted by the hypothetical state change, the process continues through block 355 with the persistence of the blueprint to fixed storage reflecting the extent of the cascading impact of the hypothetical state change to the target node or nodes.

Of import, the foregoing flowchart and block diagram referred to herein illustrate the architecture, functionality, and operation of possible implementations of systems, methods, and computing devices according to various embodiments of the present invention. In this regard, each block in the flowchart or block diagrams may represent a module, segment, or portion of instructions, which includes one or more executable instructions for implementing the specified logical function or functions. In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

More specifically, the present invention may be embodied as a programmatically executable process. As well, the present invention may be embodied within a computing device upon which programmatic instructions are stored and from which the programmatic instructions are enabled to be loaded into memory of a data processing system and executed therefrom in order to perform the foregoing programmatically executable process. Even further, the present invention may be embodied within a data processing system adapted to load the programmatic instructions from a computing device and to then execute the programmatic instructions in order to perform the foregoing programmatically executable process.

To that end, the computing device is a non-transitory computer readable storage medium or media retaining therein or storing thereon computer readable program instructions. These instructions, when executed from memory by one or more processing units of a data processing system, cause the processing units to perform different programmatic processes exemplary of different aspects of the programmatically executable process. In this regard, the processing units each include an instruction execution device such as a central processing unit or “CPU” of a computer. One or more computers may be included within the data processing system. Of note, while the CPU can be a single core CPU, it will be understood that multiple CPU cores can operate within the CPU and in either instance, the instructions are directly loaded from memory into one or more of the cores of one or more of the CPUs for execution.

Aside from the direct loading of the instructions from memory for execution by one or more cores of a CPU or multiple CPUs, the computer readable program instructions described herein alternatively can be retrieved from over a computer communications network into the memory of a computer of the data processing system for execution therein. As well, only a portion of the program instructions may be retrieved into the memory from over the computer communications network, while other portions may be loaded from persistent storage of the computer. Even further, only a portion of the program instructions may execute by one or more processing cores of one or more CPUs of one of the computers of the data processing system, while other portions may cooperatively execute within a different computer of the data processing system that is either co-located with the computer or positioned remotely from the computer over the computer communications network with results of the computing by both computers shared therebetween.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

Having thus described the invention of the present application in detail and by reference to embodiments thereof, it will be apparent that modifications and variations are possible without departing from the scope of the invention defined in the appended claims as follows:

We claim:

1. A method for critical infrastructure (CI) protection blueprint generation and utilization in an interdependent CI architecture comprising:
constructing in memory of a computer, a digital twin of a heterogeneous collection of CI elements associated with respectively different services provided to a common community, by
defining a hierarchy of the CI elements in the collection, associating different ones of the CI elements in the hierarchy with other ones of the CI elements in the hierarchy so as to create a dependency relationship therebetween,
receiving sensor data from each of the CI elements in the hierarchy over a defined period of time, and
correlating observed performance data to the sensor data, the correlation, for each one of the CI elements in the hierarchy, modeling different states of operation of the one of the CI elements resulting from different conditions reflected by the sensor data including sensed states of operation of dependent ones of the CI elements in the hierarchy;
subsequent to the construction of the digital twin, specifying in the digital twin hypothetical sensor data for a target one of the CI elements in the hierarchy;
reading in response to the specification of the hypothetical sensor data, sensor data of the other ones of the CI elements dependent upon the target one of the CI elements in the hierarchy;
computing a new state in the digital twin of each one of the other ones of the CI elements and comparing the new state for each one of the other ones of the CI elements to a previously computed state in order to identify impacted ones of the CI elements;
for each impacted one of the CI elements, additionally reading sensor data of further ones of the CI elements in the hierarchy dependent upon the impacted ones of the CI elements, computing a new state in the digital twin of each further one of the CI elements in the hierarchy and comparing the new state for each further one of the CI elements to a previously computed state in order to identify further impacted ones of the CI elements;
repeating the additional reading, computing and comparing until no additional impacted CI elements are identified; and,
adding a listing of all impacted ones of the CI elements to a blueprint for the hierarchy in association with the hypothetical sensor data in order to define a cascading effect of the hypothetical sensor data upon the hierarchy within the digital twin.

2. The method of claim 1, wherein the hypothetical sensor data is received from over a communications network by an authenticated end user of the digital twin.

3. The method of claim 2, wherein the hypothetical sensor data is a collection of sensed data for correspondingly different ones of the CI elements.

4. The method of claim 1, further comprising inserting into the blueprint, at least one configuration parameter for a corresponding one of the impacted CI elements associated with a remediation of the cascading event.

5. A data processing system adapted for critical infrastructure (CI) protection blueprint generation and utilization in an interdependent CI architecture, the system comprising:
a multiplicity of different device sensors affixed to different CI elements associated with respectively different services provided to a common community;
a host computing platform comprising one or more computers, each with memory and one or processing units including one or more processing cores, and a network interface communicatively coupled over a computer communications network to each of the different device sensors; and,
a blueprint generation module comprising computer program instructions enabled while executing in the memory of at least one of the processing units of the host computing platform to perform:
constructing in the memory a digital twin of a heterogeneous collection of the CI elements, by
defining a hierarchy of the CI elements in the collection, associating different ones of the CI elements in the hierarchy with other ones of the CI elements in the hierarchy so as to create a dependency relationship therebetween,
receiving sensor data from each of the CI elements in the hierarchy over a defined period of time, and
correlating observed performance data to the sensor data, the correlation, for each one of the CI elements in the hierarchy, modeling different states of operation of the one of the CI elements resulting from different conditions reflected by the sensor data including sensed states of operation of dependent ones of the CI elements in the hierarchy;
subsequent to the construction of the digital twin, specifying in the digital twin, hypothetical sensor data for a target one of the CI elements in the hierarchy;
reading in response to the specification of the hypothetical sensor data, sensor data of the other ones of the CI elements dependent upon the target one of the CI elements in the hierarchy;
computing a new state in the digital twin of each one of the other ones of the CI elements and comparing the new state for each one of the other ones of the CI elements to a previously computed state in order to identify impacted ones of the CI elements;
for each impacted one of the CI elements, additionally reading sensor data of further ones of the CI elements in the hierarchy dependent upon the impacted ones of the CI elements, computing a new state in the digital twin of each further one of the CI elements in the hierarchy and comparing the new state for each further one of the CI elements to a previously computed state in order to identify further impacted ones of the CI elements;
repeating the additional reading, computing and comparing until no additional impacted CI elements are identified; and,
adding a listing of all impacted ones of the CI elements to a blueprint for the hierarchy in association with the hypothetical sensor data in order to define a cascading effect of the hypothetical sensor data upon the hierarchy within the digital twin.

6. The system of claim 5, wherein the hypothetical sensor data is received from over a communications network by an authenticated end user of the digital twin.

7. The system of claim 6, wherein the hypothetical sensor data is a collection of sensed data for correspondingly different ones of the CI elements.

8. The system of claim 5, wherein the program instructions further perform inserting into the blueprint, at least one configuration parameter for a corresponding one of the impacted CI elements associated with a remediation of the cascading event.

9. A computing device comprising a non-transitory computer readable storage medium having program instructions stored therein, the instructions being executable by at least one processing core of a processing unit to cause the processing unit to perform a method for critical infrastructure (CI) protection blueprint generation and utilization in an interdependent CI architecture, the method including:
constructing in memory of a computer, a digital twin of a heterogeneous collection of CI elements associated with respectively different services provided to a common community, by
defining a hierarchy of the CI elements in the collection, associating different ones of the CI elements in the hierarchy with other ones of the CI elements in the hierarchy so as to create a dependency relationship therebetween,
receiving sensor data from each of the CI elements in the hierarchy over a defined period of time, and
correlating observed performance data to the sensor data, the correlation, for each one of the CI elements in the hierarchy, modeling different states of operation of the one of the CI elements resulting from different conditions reflected by the sensor data including sensed states of operation of dependent ones of the CI elements in the hierarchy;
subsequent to the construction of the digital twin, specifying in the digital twin, hypothetical sensor data for a target one of the CI elements in the hierarchy;
reading in response to the specification of the hypothetical sensor data, sensor data of the other ones of the CI elements dependent upon the target one of the CI elements in the hierarchy;
computing a new state in the digital twin of each one of the other ones of the CI elements and comparing the new state for each one of the other ones of the CI elements to a previously computed state in order to identify impacted ones of the CI elements;
for each impacted one of the CI elements, additionally reading sensor data of further ones of the CI elements in the hierarchy dependent upon the impacted ones of the CI elements, computing a new state in the digital twin of each further one of the CI elements in the hierarchy and comparing the new state for each further one of the CI elements to a previously computed state in order to identify further impacted ones of the CI elements;
repeating the additional reading, computing and comparing until no additional impacted CI elements are identified; and,
adding a listing of all impacted ones of the CI elements to a blueprint for the hierarchy in association with the hypothetical sensor data in order to define a cascading effect of the hypothetical sensor data upon the hierarchy within the digital twin.

10. The device of claim 9, wherein the hypothetical sensor data is received from over a communications network by an authenticated end user of the digital twin.

11. The device of claim 10, wherein the hypothetical sensor data is a collection of sensed data for correspondingly different ones of the CI elements.

12. The device of claim 9, wherein the method further includes inserting into the blueprint, at least one configuration parameter for a corresponding one of the impacted CI elements associated with a remediation of the cascading event.
